(19) United States
(12) Patent Application Publication
(10) Pub. No.: US 2018/0188618 A1
(43) Pub. Date: Jul. 5, 2018

(54) MANUFACTURING METHOD OF FRINGE FIELD SWITCHING ARRAY SUBSTRATE

(71) Applicant: SHENZHEN CHINA STAR OPTOELECTRONICS TECHNOLOGY CO., LTD., Shenzhen (CN)

(72) Inventor: Shimin GE, Shenzhen (CN)

(21) Appl. No.: 14/891,904

(22) PCT Filed: Aug. 18, 2015
(86) PCT No.: PCT/CN2015/087379

§ 371 Date: Nov. 17, 2015

(30) Foreign Application Priority Data
Aug. 12, 2015 (CN) 201510493112.X

(51) Int. Cl. G02F 1/1343; G02F 1/1368; H01L 27/12

(52) U.S. Cl. CPC G02F 1/134363; G02F 1/1368; G02F 1/13439; G02F 2001/136231; H01L 27/1288; H01L 27/127; H01L 27/1225

(57) ABSTRACT

A manufacturing method of a fringe field switching (FFS) array substrate is provided. The method has steps of: forming gate electrodes and common electrodes on a glass substrate, wherein the gate electrodes are formed on a portion of the common electrodes; forming semiconductor active layer precursors and pixel electrode precursors; and executing an ion implantation process for two ends of each of the semiconductor active layer precursors which are uncovered by a photoresist layer, so as to transform they into transparent conductors; and finally forming source electrodes and drain electrodes.

### FIELD OF THE INVENTION

The present invention relates to a technological field of liquid crystal displays, and more particularly to a manufacturing method of a fringe field switching (FFS) array substrate.

### BACKGROUND OF THE INVENTION

A fringe field switching (FFS) technology is one of technologies of liquid crystal displays (LCDs) nowadays, and is a kind of wide viewing angle (WVA) technology developed for application of desktop displays and LCD TVs having a large size and high resolution. An FFS liquid crystal panel has advantages of: quick response time, high light transmission rate, wide viewing angle, low color cast, etc.

Now, an amorphous silicon (a-Si) and a poly-silicon (p-Si) are semiconductor mainstream materials of a thin film transistor (TFT). The amorphous silicon has been used widely, but has problems of low electron mobility ratio and poor illumination stability. The electron mobility ratio of the poly-silicon is better than that of the amorphous silicon, but the poly-silicon has problems of complex structures, high leakage current, and poor uniformity in the film quality. As described above, with the rapid development of LCD technology, the capability of the TFT is required more and more by people, and the amorphous silicon and the poly-silicon cannot satisfy the requirement any more.

Furthermore, pixel electrodes are commonly manufactured by a transparent material of an indium tin oxide (ITO). When manufacturing semiconductor active layers and pixel electrodes of a TFT, it is necessary to have two mask processes, by which the semiconductor active layers and the pixel electrodes are respectively manufactured. However, it means more masks are used and the manufacturing processes will be more complex, so that the manufacturing effect is decreased.

### SUMMARY OF THE INVENTION

The object of the present invention is to provide a manufacturing method of a fringe field switching (FFS) array substrate, by which the number of mask can be reduced, so as to increase the manufacturing effect of the FFS array substrate.

The technical solutions of the present invention are:

A manufacturing method of a fringe field switching (FFS) array substrate, comprising steps of:

forming gate electrodes and common electrodes on a glass substrate, wherein the gate electrodes are formed on a portion of the common electrodes;

forming a gate electrode insulation layer on the gate electrodes and the common electrodes;

depositing a transparent metal oxide semiconductor layer on the gate electrode insulation layer;

executing one pattern process onto the transparent metal oxide semiconductor layer, so as to form semiconductor active layer precursors and pixel electrode precursors, and photoresist layers are formed on a middle portion of each of the semiconductor active layer precursors;

executing an ion implantation process for two ends of each of the semiconductor active layer precursors which are uncovered by the photoresist layer and the pixel electrode precursors, so as to transform the two ends of each of the semiconductor active layer precursors and the pixel electrode precursors into transparent conductors, wherein the semiconductor active layer precursors are formed as semiconductor active layers, and the pixel electrode precursors are formed as pixel electrodes;

forming source electrodes and drain electrodes on the semiconductor active layers; and

forming a passivation layer on the source electrodes, the drain electrodes, the semiconductor active layers, and the pixel electrodes.

Preferably, the step of forming the gate electrodes and the common electrodes is: firstly, an indium tin oxide (ITO) layer and a metal layer are deposited on the glass substrate in order; and then the ITO layer and the metal layer are executed one pattern process, so as to form the gate electrodes and the common electrodes.

Preferably, a material of the transparent metal oxide semiconductor layer is an indium gallium zinc oxide (IGZO).

Preferably, a material of the transparent metal oxide semiconductor layer is an indium tin zinc oxide (ITZO).

Preferably, the method of the ion implantation process is: the two ends of each of the semiconductor active layer precursors and the pixel electrode precursors are executed a plasmas process.

Preferably, the ion of the ion implantation is a hydrogen (H) ion.

Preferably, the ion of the ion implantation is an argon (Ar) ion.

Preferably, before the step of forming the source electrodes and the drain electrodes on the semiconductor active layers, the method further comprises a step of: forming an etching barrier layer on the semiconductor active layers and the pixel electrodes, and forming a plurality of vias on the etching barrier layer which corresponds to the two ends of each of the semiconductor active layers and one end closed to the semiconductor active layers of each of the pixel electrodes, so as to expose the two ends of each of the semiconductor active layers and the one end closed to the semiconductor active layers of each of the pixel electrodes.

Preferably, a manufacturing material of the etching barrier layer is a silica.

A manufacturing method of a fringe field switching (FFS) array substrate, comprising steps of:

forming gate electrodes and common electrodes on a glass substrate, wherein the gate electrodes are formed on a portion of the common electrodes;

forming a gate electrode insulation layer on the gate electrodes and the common electrodes;

depositing a transparent metal oxide semiconductor layer on the gate electrode insulation layer;

executing one pattern process onto the transparent metal oxide semiconductor layer, so as to form semiconductor active layer precursors and pixel electrode precursors, and photoresist layers are formed on a middle portion of each of the semiconductor active layer precursors;

executing an ion implantation process for two ends of each of the semiconductor active layer precursors which are uncovered by the photoresist layer and the pixel electrode precursors, so as to transform the two ends of each of the semiconductor active layer precursors and the pixel electrode precursors into transparent conductors, wherein the semiconductor active layer precursors are formed as semiconductor active layers, and the pixel electrode precursors are formed as pixel electrodes; and forming source electrodes and drain electrodes on the semiconductor active layers.

Preferably, the method further comprises a step of: forming a passivation layer on the source electrodes, the drain electrodes, the semiconductor active layers, and the pixel electrodes.

Preferably, the step of forming the gate electrodes and the common electrodes is: firstly, an indium tin oxide (ITO) layer and a metal layer are deposited on the glass substrate in order; and then the ITO layer and the metal layer are executed one pattern process, so as to form the gate electrodes and the common electrodes.

Preferably, a material of the transparent metal oxide semiconductor layer is an indium gallium zinc oxide (IGZO).

Preferably, a material of the transparent metal oxide semiconductor layer is an indium tin zinc oxide (ITZO).

Preferably, the method of the ion implantation process is: the two ends of each of the semiconductor active layer precursors and the pixel electrode precursors are executed a plasmas process.

Preferably, the ion of the ion implantation is a hydrogen (H) ion.

Preferably, the ion of the ion implantation is an argon (Ar) ion.

Preferably, before the step of forming the source electrodes and the drain electrodes on the semiconductor active layers, the method further comprises a step of: forming an etching barrier layer on the semiconductor active layers and the pixel electrodes, and forming a plurality of vias on the semiconductor active layers which corresponds to the two ends of each of the semiconductor active layers and one end closed to the semiconductor active layers of each of the pixel electrodes, so as to expose the two ends of each of the semiconductor active layers and the one end closed to the semiconductor active layers of each of the pixel electrodes.

Preferably, a manufacturing material of the gate electrode insulation layer is a silica.

Preferably, a manufacturing material of the gate electrode insulation layer is a silica/silicon nitride double film.

The advantageous effects of the present invention are:

In the manufacturing method of the FFS array substrate, gate electrodes and common electrodes are simultaneously manufactured by one mask, and semiconductor active layers and pixel electrodes are simultaneously manufactured by one mask. It can reduced the times of the mask processes, decrease the manufacturing cost, and increase the manufacturing effect of the FFS array substrate. Additionally, because it uses the metal oxide semiconductor to replace amorphous silicon (a-Si) and poly-silicon (p-Si) as semiconductor materials of a thin film transistor (TFT), the electron mobility ratio and aperture ratio thereof are increased, and the illumination stability and the illumination penetration are better.

### DESCRIPTION OF THE DRAWINGS

FIG. 1 is a flow chart of a manufacturing method according to an embodiment 1;

FIG. 2 is a structural schematic view showing gate electrodes and common electrodes is formed on a substrate according to the embodiment 1 of the present invention;

FIG. 3 is a structural schematic view showing a gate electrode insulation layer is formed according to the substrate of the embodiment 1 of the present invention;

FIG. 4 is a schematic view showing semiconductor active layer precursors and pixel electrode precursors are covered by photoresist layers when executing one pattern process onto a metal oxide semiconductor layer according to the substrate of the embodiment 1 of the present invention;

FIG. 5 is a schematic view showing a middle portion of each of the semiconductor active layer precursors are covered by the photoresist layers according to the substrate of the embodiment 1 of the present invention;

FIG. 6 is a schematic view showing the semiconductor active layer precursors and the pixel electrode precursors are respectively formed as semiconductor active layers and the pixel electrodes after executed an ion implantation process according to the substrate of the embodiment 1 of the present invention;

FIG. 7 is a schematic view showing source electrodes and the drain electrodes are formed on the semiconductor active layers according to the substrate of the embodiment 1 of the present invention;

FIG. 8 is a schematic view showing the source electrodes, the drain electrodes, and the pixel electrodes are covered by a passivation layer according to the substrate of the embodiment 1 of the present invention;

FIG. 9 is a schematic view showing the semiconductor active layers and the pixel electrodes are covered by an etching barrier layer according to a substrate of an embodiment 2 of the present invention;

FIG. 10 is a schematic view showing source electrodes and drain electrodes are formed on the etching barrier layer according to the substrate of the embodiment 2 of the present invention; and

FIG. 11 is a schematic view showing a passivation layer is formed on the source electrodes, the drain electrodes, and the etching barrier layer according to the substrate of the embodiment 2 of the present invention.

### DETAILED DESCRIPTION OF THE PREFERRED EMBODIMENTS

The foregoing objects, features, and advantages adopted by the present invention can be best understood by referring to the following detailed description of the preferred embodiments and the accompanying drawings. Furthermore, the directional terms described in the present invention, such as upper, lower, front, rear, left, right, inner, outer, side, etc., are only directions with reference to the accompanying drawings, so that the used directional terms are used to describe and understand the present invention, but the present invention is not limited thereto. In the drawings, units with similar structures use the same numerals.

### Embodiment 1

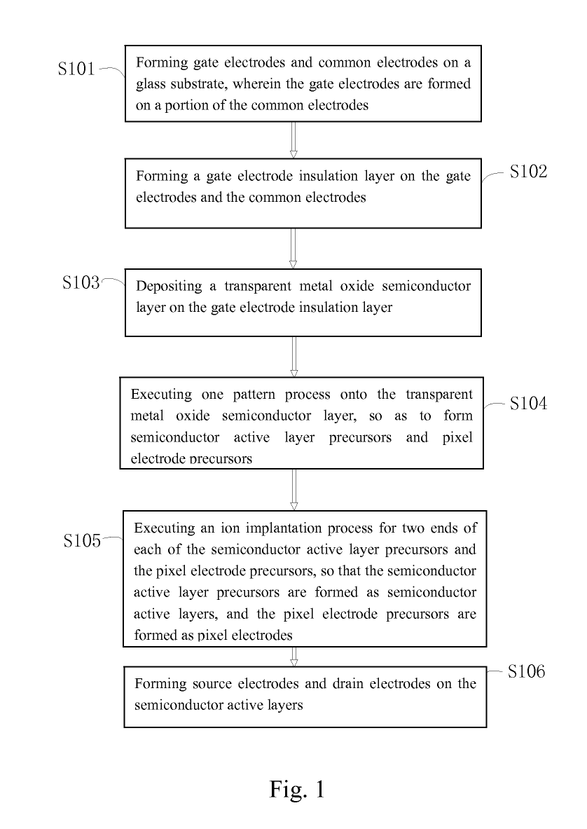

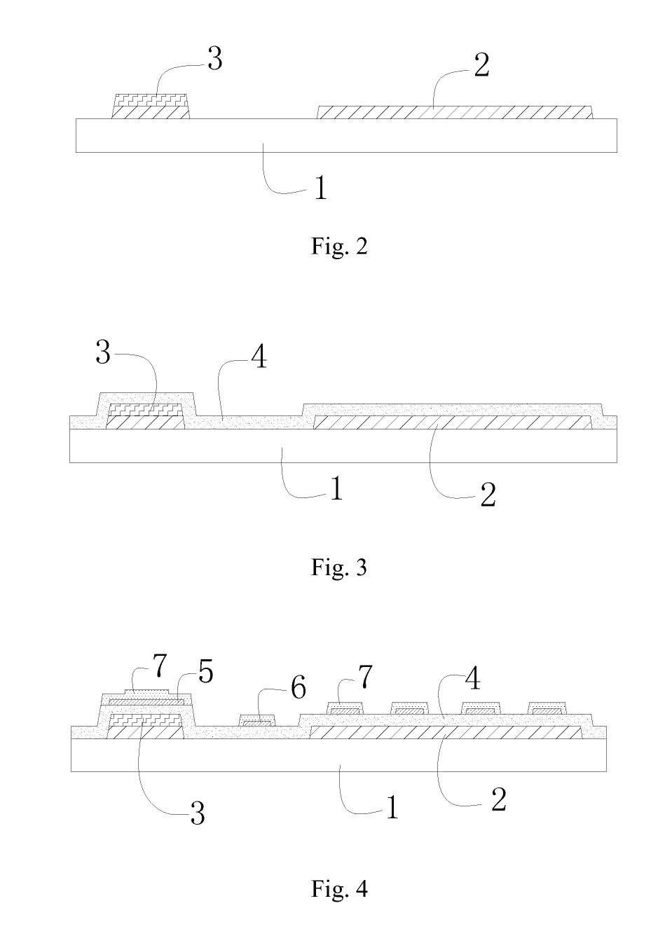

FIG. 1 is a flow chart of a manufacturing method of a fringe field switching (FFS) array substrate according to the embodiment 1; and FIGS. 2-8 are sequence views of manufacturing the FFS array substrate according to the embodiment.

As shown in FIG. 1, a manufacturing method of an FFS array substrate according to the embodiment comprises following steps of:

S101: as shown in FIG. 2, forming gate electrodes 3 and common electrodes 2 on a glass substrate 1, wherein the gate electrodes 3 are formed on a portion of the common electrodes 2. The specific process is: firstly, an indium tin oxide (ITO) layer is deposited on the glass substrate 1, and a metal layer is deposited on the ITO layer, wherein the material of the metal layer can be copper or aluminum, or other metals; next, the ITO layer and the metal layer are executed a pattern process, namely, the gate electrodes 3 and the common electrodes 2 are formed by one mask process, which includes processes of coating a photoresist, exposing, developing, etching, and removing the photoresist. In the step, for forming the gate electrodes 3 and the common electrodes 2 with only one mask process, the gate electrodes 3 are formed on a portion of the ITO layer which is separated with the common electrodes 2. In a conventional technology, it is first to form a gate electrodes 3 on a glass substrate 1, and form a gate electrode insulation layer 4 on the gate electrodes 3, and then form a common electrodes 2 on the gate electrode insulation layer 4, so that this kind of method needs two mask processes separately executed to be finished. Therefore, comparing the step with the conventional technology, because one of the mask processes is reduced, it can decrease the manufacturing cost.

S102: as shown in FIG. 3, a structural schematic view showing a gate electrode insulation layer is formed according to the substrate of the embodiment. In the step, a gate electrode insulation layer 4 is formed on the gate electrodes 3 and the common electrodes 2. A manufacturing material of the gate electrode insulation layer 4 can be a silica or a silicon nitride, and preferably, it is a silica or a silica/silicon nitride double film, but it also can be other proper materials. The gate electrode insulation layer 4 is deposited and formed by a method of plasma enhanced chemical vapor deposition (PECVD).

S103: depositing a transparent metal oxide semiconductor layer on the gate electrode insulation layer 4. A material of the transparent metal oxide semiconductor layer is an indium gallium zinc oxide (IGZO) or an indium tin zinc oxide (ITZO). The IGZO is preferable in the embodiment.

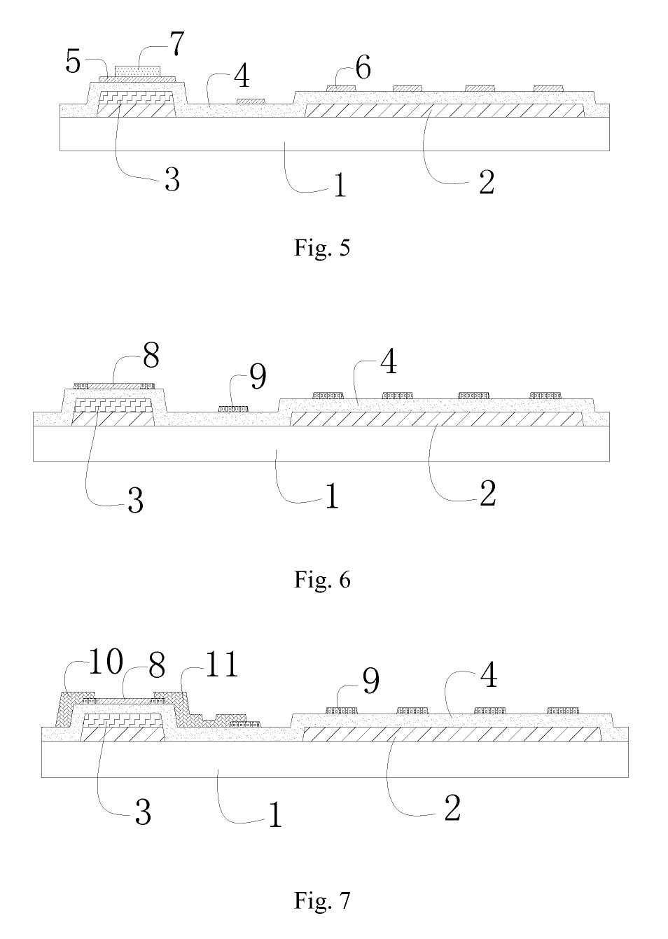

S104: executing one pattern process onto the transparent metal oxide semiconductor layer, namely the IGZO layer, to form semiconductor active layer precursors 5 and pixel electrode precursors 6, and to form photoresist layers 7 on a middle portion of each of the semiconductor active layer precursors 5. The pattern process includes processes of coating, exposing, developing, etching, and removing the photoresist layers 7. One of particular features of the embodiment is: when removing the photoresist layers 7, the photoresist layers 7 on the pixel electrode precursors 6 are all removed, but for the semiconductor active layer precursors 5, only the photoresist layers 7 on two ends thereof are removed, but the photoresist layers 7 on a middle portion thereof are kept. The photoresist layers 7 on the middle portion of each of the semiconductor active layer precursors 5 can be a protective layer for an ion implantation process in next step. As shown in FIG. 4, a schematic view showing the semiconductor active layer precursors 5 and the pixel electrode precursors 6 are covered by the photoresist layers 7 when executing the pattern process to the metal oxide semiconductor layer according to the glass substrate of the embodiment. As shown in FIG. 5, a schematic view showing the middle portion of each of the semiconductor active layer precursors 5 are covered by the photoresist layers 7 according to the glass substrate 1 of the embodiment.

S105: executing an ion implantation process for two ends of each of the semiconductor active layer precursors 5 which are uncovered by the photoresist layer 7 and the pixel electrode precursors 6, so as to transform they (the two ends of each of the semiconductor active layer precursors 5 and the pixel electrode precursors 6) into transparent conductors, wherein the semiconductor active layer precursors 5 are formed as semiconductor active layers 8 and the pixel electrode precursors 6 are formed as pixel electrodes 9. The method of the ion implantation process of the embodiment is: the two ends of each of the semiconductor active layer precursors 5 and the pixel electrode precursors 6 are executed a plasmas process. In the step, during the ion implantation process, because the middle portion of each of the semiconductor active layer precursors 5 is protected by the photoresist layers 7, the middle portion of each of the semiconductor active layer precursors 5 is not influenced and damaged by the ion implantation, so it still is a semiconductor, but the two ends of each of the semiconductor active layer precursors 5 and the pixel electrode precursors 6 are all become as conductors because they are not protected by the photoresist layers 7. Additionally, the ion of the ion implantation is a hydrogen (H) ion or an argon (Ar) ion. As shown in FIG. 6, a schematic view showing the semiconductor active layer precursors 5 and the pixel electrode precursors 6 are respectively formed as the semiconductor active layers 8 and the pixel electrodes 9 after executed the ion implantation process according to the glass substrate 1 of the embodiment.

From the steps S104 and S105, it shows that: when manufacturing the semiconductor active layers 8 and the pixel electrodes 9, only one mask process is required. Additionally, because the embodiment uses the metal oxide semiconductor, namely indium gallium zinc oxide (IGZO), to replace conventional amorphous silicon (a-Si) and poly-silicon (p-Si) as semiconductor materials of the semiconductor active layers 8 of a thin film transistor (TFT), the electron mobility ratio and aperture ratio of the semiconductor active layers 8 are increased, and the illumination stability and the illumination penetration are better. In the conventional technology, the pixel electrodes 9 is commonly made by an ITO process, so that the semiconductor active layers 8 and the pixel electrodes 9 are necessary to have two mask processes to be finished, and the effect thereof is not better than that of the embodiment.

S106: forming source electrodes 10 and drain electrodes 11 on the semiconductor active layers 8. As shown in FIG. 7, a schematic view showing the source electrodes 10 and the drain electrodes 11 are formed on the semiconductor active layers 8 according to the glass substrate 1 of the embodiment.

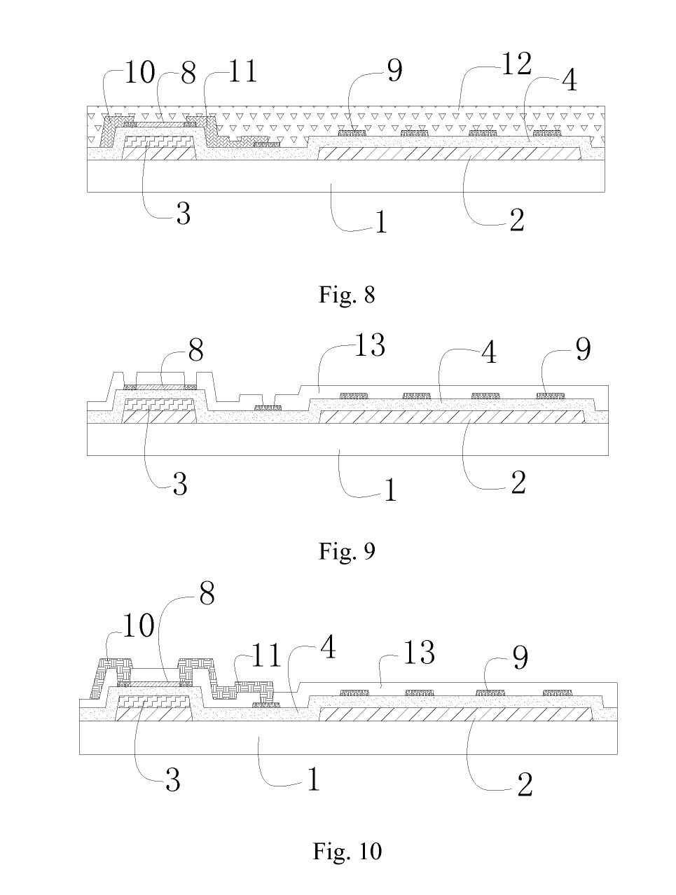

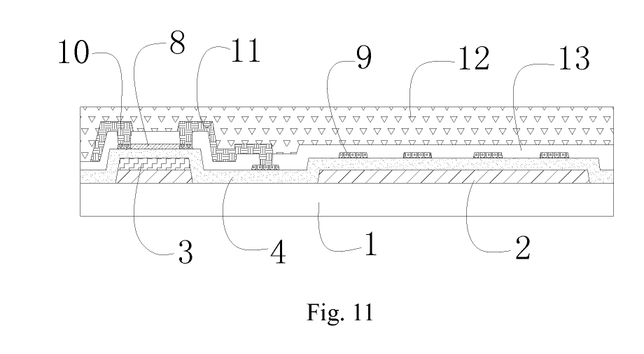

Except the above-mentioned steps, the embodiment further comprises a step of: forming a passivation layer 12 on the source electrodes 10, the drain electrodes 11, the semiconductor active layers 8, and the pixel electrodes 9. As shown in FIG. 8, a schematic view showing the source electrodes 10, the drain electrodes 11, and the pixel electrodes 9 are covered by the passivation layer 12 according to the glass substrate 1 of the embodiment 1 of the present invention.

### Embodiment 2

The front part of this embodiment is the same as steps S101-S105 of the embodiment 1, and the differences are after step S105 and before the step of forming the source electrodes 10 and the drain electrodes 11 on the semiconductor active layers 8. The method further comprises steps of: forming an etching barrier layer 13 on the semiconductor active layers 8 and the pixel electrodes 9. A manufacturing material of the etching barrier layer 13 is a silica. Furthermore, a plurality of vias are formed on the s etching barrier layer 13 which corresponds to the two ends of each of the semiconductor active layers 8 and one end closed to the semiconductor active layers 8 of each of the pixel electrodes 9, so as to expose the two ends of each of the semiconductor active layers 8 and the one end closed to the semiconductor active layers 8 of each of the pixel electrodes 9, to prepare for the next step of forming the source electrodes 10 and the drain electrodes 11.

Next, the source electrodes 10 and the drain electrodes 11 are formed on the semiconductor active layers 8 corresponding to the etching barrier layer 13. In the previous step, because the semiconductor active layers 8 and the pixel electrodes 9 are covered with the etching barrier layer 13, the middle portion of each of the semiconductor active layer 8 is not damaged in the process. Finally, a passivation layer 12 is formed on the source electrodes 10, the drain electrodes 11, and the etching barrier layer 13, so that all of the processes are finished.

The present invention has been described with preferred embodiments thereof and it is understood that many changes and modifications to the described embodiment can be carried out without departing from the scope and the spirit of the invention that is intended to be limited only by the appended claims.

1. A manufacturing method of a fringe field switching (FFS) array substrate, comprising steps of:
forming gate electrodes and common electrodes on a glass substrate, wherein the gate electrodes are formed on a portion of the common electrodes;
forming a gate electrode insulation layer on the gate electrodes and the common electrodes;
depositing a transparent metal oxide semiconductor layer on the gate electrode insulation layer;
executing one pattern process onto the transparent metal oxide semiconductor layer, so as to form semiconductor active layer precursors and pixel electrode precursors, and photoresist layers are formed on a middle portion of each of the semiconductor active layer precursors;
executing an ion implantation process for two ends of each of the semiconductor active layer precursors which are uncovered by the photoresist layer and the pixel electrode precursors, so as to transform the two ends of each of the semiconductor active layer precursors and the pixel electrode precursors into transparent conductors, wherein the semiconductor active layer precursors are formed as semiconductor active layers, and the pixel electrode precursors are formed as pixel electrodes;
forming source electrodes and drain electrodes on the semiconductor active layers; and
forming a passivation layer on the source electrodes, the drain electrodes, the semiconductor active layers, and the pixel electrodes.

2. The manufacturing method of the FFS array substrate according to claim 1, wherein the step of forming the gate electrodes and the common electrodes is: firstly, an indium tin oxide (ITO) layer and a metal layer are deposited on the glass substrate in order; and then the ITO layer and the metal layer are executed one pattern process, so as to form the gate electrodes and the common electrodes.

3. The manufacturing method of the FFS array substrate according to claim 1, wherein a material of the transparent metal oxide semiconductor layer is an indium gallium zinc oxide (IGZO).

4. The manufacturing method of the FFS array substrate according to claim 1, wherein a material of the transparent metal oxide semiconductor layer is an indium tin zinc oxide (ITZO).

5. The manufacturing method of the FFS array substrate according to claim 1, wherein the method of the ion implantation process is: the two ends of each of the semiconductor active layer precursors and the pixel electrode precursors are executed a plasmas process.

6. The manufacturing method of the FFS array substrate according to claim 1, wherein the ion of the ion implantation is a hydrogen (H) ion.

7. The manufacturing method of the FFS array substrate according to claim 1, wherein the ion of the ion implantation is an argon (Ar) ion.

8. The manufacturing method of the FFS array substrate according to claim 1, wherein before the step of forming the source electrodes and the drain electrodes on the semiconductor active layers, the method further comprises a step of: forming an etching barrier layer on the semiconductor active layers and the pixel electrodes, and forming a plurality of vias on the etching barrier layer which corresponds to the two ends of each of the semiconductor active layers and one end closed to the semiconductor active layers of each of the pixel electrodes, so as to expose the two ends of each of the semiconductor active layers and the one end closed to the semiconductor active layers of each of the pixel electrodes.

9. The manufacturing method of the FFS array substrate according to claim 1, wherein a manufacturing material of the etching barrier layer is a silica.

10. A manufacturing method of a fringe field switching (FFS) array substrate, comprising steps of:
forming gate electrodes and common electrodes on a glass substrate, wherein the gate electrodes are formed on a portion of the common electrodes;
forming a gate electrode insulation layer on the gate electrodes and the common electrodes;
depositing a transparent metal oxide semiconductor layer on the gate electrode insulation layer;
executing one pattern process onto the transparent metal oxide semiconductor layer, so as to form semiconductor active layer precursors and pixel electrode precursors, and photoresist layers are formed on a middle portion of each of the semiconductor active layer precursors;
executing an ion implantation process for two ends of each of the semiconductor active layer precursors which are uncovered by the photoresist layer and the pixel electrode precursors, so as to transform the two ends of each of the semiconductor active layer precursors and the pixel electrode precursors into transparent conductors, wherein the semiconductor active layer precursors are formed as semiconductor active layers, and the pixel electrode precursors are formed as pixel electrodes; and
forming source electrodes and drain electrodes on the semiconductor active layers.

11. The manufacturing method of the FFS array substrate according to claim 10, wherein the method further comprises a step of: forming a passivation layer on the source electrodes, the drain electrodes, the semiconductor active layers, and the pixel electrodes.

12. The manufacturing method of the FFS array substrate according to claim 10, wherein the step of forming the gate electrodes and the common electrodes is: firstly, an indium tin oxide (ITO) layer and a metal layer are deposited on the glass substrate in order; and then the ITO layer and the metal layer are executed one pattern process, so as to form the gate electrodes and the common electrodes.

13. The manufacturing method of the FFS array substrate according to claim 10, wherein a material of the transparent metal oxide semiconductor layer is an indium gallium zinc oxide (IGZO).

14. The manufacturing method of the FFS array substrate according to claim 10, wherein a material of the transparent metal oxide semiconductor layer is an indium tin zinc oxide (ITZO).

15. The manufacturing method of the FFS array substrate according to claim 10, wherein the method of the ion implantation process is: the two ends of each of the semiconductor active layer precursors and the pixel electrode precursors are executed a plasmas process.

16. The manufacturing method of the FFS array substrate according to claim 10, wherein the ion of the ion implantation is a hydrogen (H) ion.

17. The manufacturing method of the FFS array substrate according to claim 10, wherein the ion of the ion implantation is an argon (Ar) ion.

18. The manufacturing method of the FFS array substrate according to claim 10, wherein before the step of forming the source electrodes and the drain electrodes on the semiconductor active layers, the method further comprises a step of: forming an etching barrier layer on the semiconductor active layers and the pixel electrodes, and forming a plurality of vias on the semiconductor active layers which corresponds to the two ends of each of the semiconductor active layers and one end closed to the semiconductor active layers of each of the pixel electrodes, so as to expose the two ends of each of the semiconductor active layers and the one end closed to the semiconductor active layers of each of the pixel electrodes.

19. The manufacturing method of the FFS array substrate according to claim 10, wherein a manufacturing material of the gate electrode insulation layer is a silica.

20. The manufacturing method of the FFS array substrate according to claim 1, wherein a manufacturing material of the gate electrode insulation layer is a silica/silicon nitride double film.
